(19) United States
(12) Patent Application Publication
(10) Pub. No.: US 2016/0358794 A1
(43) Pub. Date: Dec. 8, 2016

(54) SUBSTRATE PROCESSING APPARATUS AND SUBSTRATE PROCESSING METHOD

(71) Applicant: Tokyo Electron Limited, Tokyo (JP)

(72) Inventor: Shigehiro MIURA, Iwate (JP)

(21) Appl. No.: 15/158,788

(22) Filed: May 19, 2016

(30) Foreign Application Priority Data
Jun. 2, 2015 (JP) 2015-111907

(51) Int. Cl. H01L 21/67; H01L 21/311; H01J 37/32; H01L 21/02

(52) U.S. Cl. CPC H01L 21/67069; H01L 21/67098; H01L 21/02164; H01L 21/02252; H01L 21/31116; H01J 37/32009; H01J 37/3244; H01J 2237/334

(57) ABSTRACT

A substrate processing apparatus includes a vacuum chamber and a turntable provided in the vacuum chamber. The turntable includes a substrate receiving area formed in a surface along a circumferential direction thereof. An etching area is provided at a predetermined area along the circumferential direction of the turntable. An etching gas supply unit is provided in the etching area so as to face the surface of the turntable and including gas discharge holes arranged extending in a radial direction of the turntable. A reaction energy decrease prevention unit configured to prevent a decrease in etching reaction energy in an outer area of the turntable in the etching area is provided.

### CROSS-REFERENCE TO RELATED APPLICATIONS

This patent application is based upon and claims the benefit of priority of Japanese Patent Application No. 2015-111907, filed on Jun. 2, 2015, the entire contents of which are incorporated herein by reference.

### BACKGROUND OF THE INVENTION

1. Field of the Invention

The present invention generally relates to a substrate processing apparatus and a substrate processing method.

2. Description of the Related Art

Conventionally, as described in Japanese Laid-Open Patent Application Publication No. 2012-209394, a film deposition apparatus including a film deposition area and an etching area in a process chamber is known. The film deposition apparatus described in Japanese Laid-Open Patent Application Publication No. 2012-209394 includes a first reaction gas supply part for supplying a first reaction gas to a substrate placed on a turntable provided in a vacuum chamber, and a second reaction gas supply part provided apart from the first reaction gas supply part in a circumferential direction of the turntable for supplying a second reaction gas that reacts with the first reaction gas adsorbed on the substrate, thereby depositing a reaction product. The film deposition apparatus further includes an activated gas supply part provided apart from both of the first reaction gas supply part and the second reaction gas supply part and configured to activate a treatment gas for improving the reaction product and an etching gas for etching the reaction product, and to supply the activated gas to the substrate. Thus, the film deposition apparatus is configured to be able to improve and etch the reaction product.

However, the film deposition process and the etching process require different conditions from each other to achieve a uniform film deposition process and a uniform etching process, respectively. Hence, achieving the uniform etching process is often difficult by just providing the etching area in the film deposition apparatus.

### SUMMARY OF THE INVENTION

Embodiments of the present invention provide a substrate processing apparatus and a substrate processing method that can perform a uniform etching process.

According to one embodiment of the present invention, there is provided a substrate processing apparatus that includes a vacuum chamber and a turntable provided in the vacuum chamber. The turntable includes a substrate receiving area formed in a surface along a circumferential direction thereof. An etching area is provided at a predetermined area along the circumferential direction of the turntable. An etching gas supply unit is provided in the etching area so as to face the surface of the turntable and including gas discharge holes arranged extending in a radial direction of the turntable. A reaction energy decrease prevention unit configured to prevent a decrease in etching reaction energy in an outer area of the turntable in the etching area is provided.

According to another embodiment of the present invention, there is provided a substrate processing method. In the method, a substrate is placed on a substrate receiving area formed in a surface of a turntable along a circumferential direction of the turntable that is provided in a process chamber. An etching process is performed on the substrate by rotating the turntable to cause the substrate to pass through an etching area provided at a predetermined area in the circumferential direction of the turntable. Here, the etching process is performed while preventing a decrease in etching reaction energy in an outer area of the turntable in the etching area.

### BRIEF DESCRIPTION OF THE DRAWINGS

FIG. 1 is a schematic cross-sectional view of a substrate processing apparatus according to an embodiment of the present invention;

FIG. 2 is a schematic plan view of a substrate processing apparatus according to an embodiment of the present invention;

FIG. 3 is a partial cross-sectional view illustrating separation areas in the substrate processing apparatus according to an embodiment of the present invention;

FIG. 4 is another partial cross-sectional view of a substrate processing apparatus according to an embodiment of the present invention;

FIG. 5 is a partial cross-sectional view illustrating a third process region of a substrate processing apparatus according to an embodiment of the present invention;

FIG. 6 is a plan view illustrating an example of a lower surface of a shower head unit of a substrate processing apparatus according to an embodiment of the present invention;

FIG. 7 is a diagram illustrating a substrate processing apparatus according to an embodiment of the present invention;

FIG. 8 is a diagram illustrating an arrangement relationship between a downward protruding portion and a turntable when removing a shower head unit of a substrate processing apparatus according to an embodiment of the present invention;

FIG. 9 is a diagram illustrating an example of a substrate processing apparatus according to an embodiment of the present invention;

FIG. 10 is a substrate processing apparatus according to an embodiment of the present invention;

FIGS. 11A and 11B are diagrams showing experiments of measuring an amount of etching while changing a distribution of gas discharge holes of a shower head unit and results thereof;

FIG. 12 is a diagram showing a pressure distribution simulation result of an area below a shower head of a substrate processing apparatus of a comparative example;

FIG. 13 is a diagram showing a pressure distribution simulation result of an area below a shower head of a substrate processing apparatus of a working example;

FIG. 14 is a diagram showing pressure dependency of an etching rate of a substrate processing apparatus of a comparative example; and

FIG. 15 is a diagram showing a simulation result of having calculated a preferable etching rate based on the pressure dependency of the etching rate of FIG. 14.

### DESCRIPTION OF THE PREFERRED EMBODIMENTS

In the following, embodiments of the present invention will be described with reference to the accompanying drawings.

### First Embodiment

(Substrate Processing Apparatus)

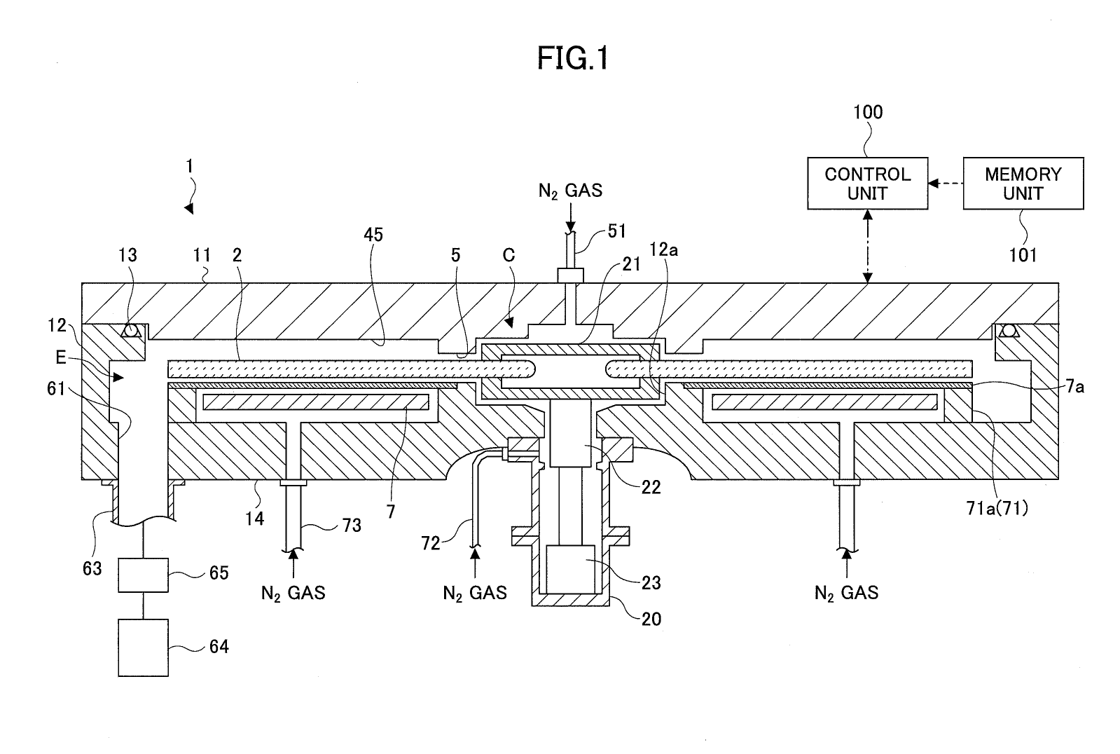

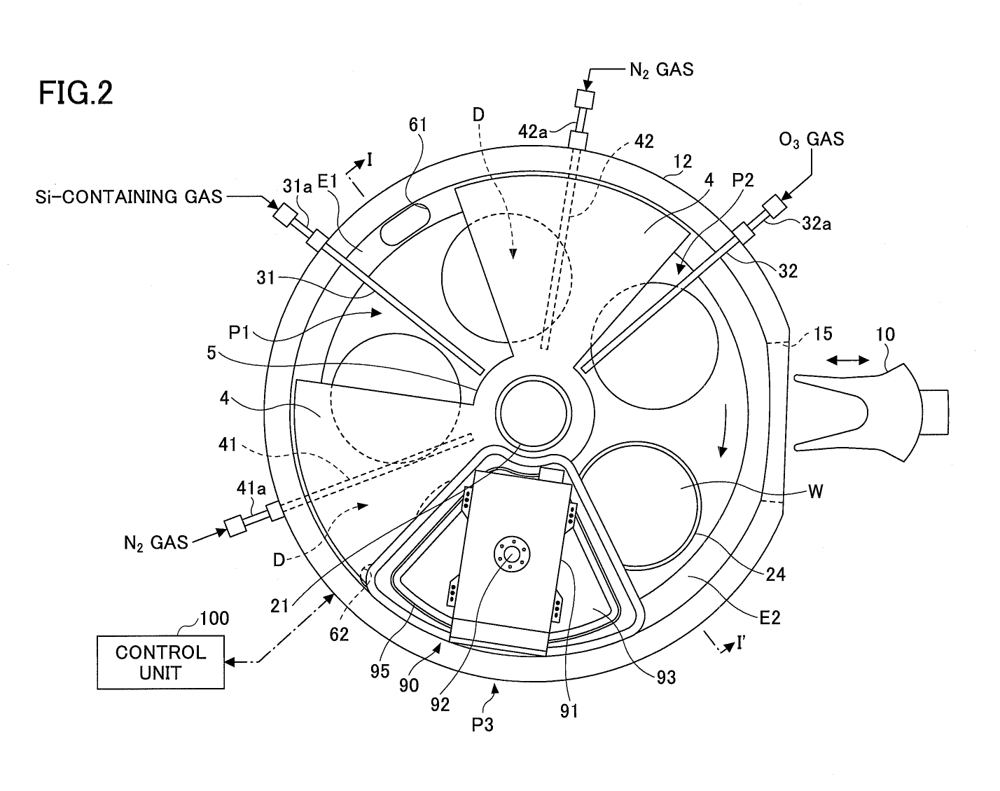

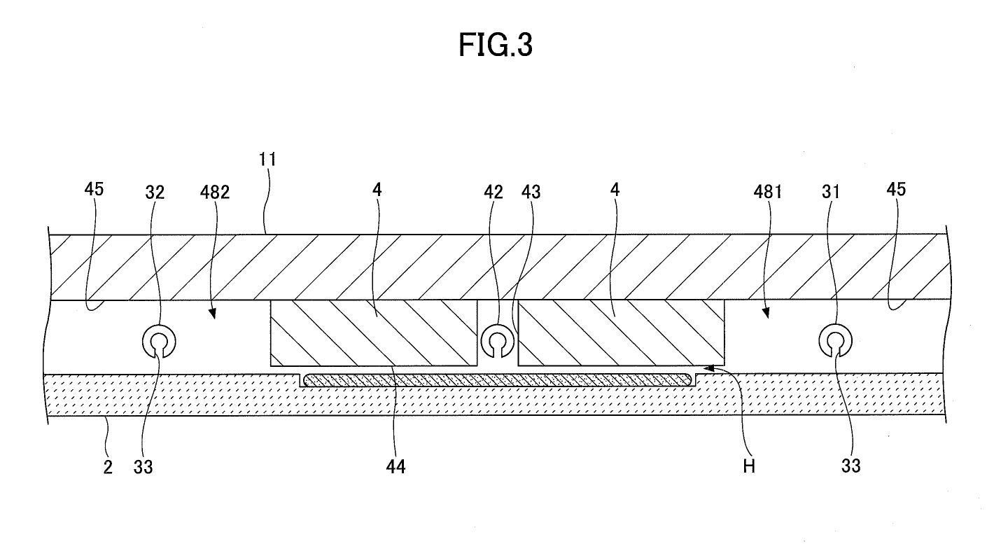

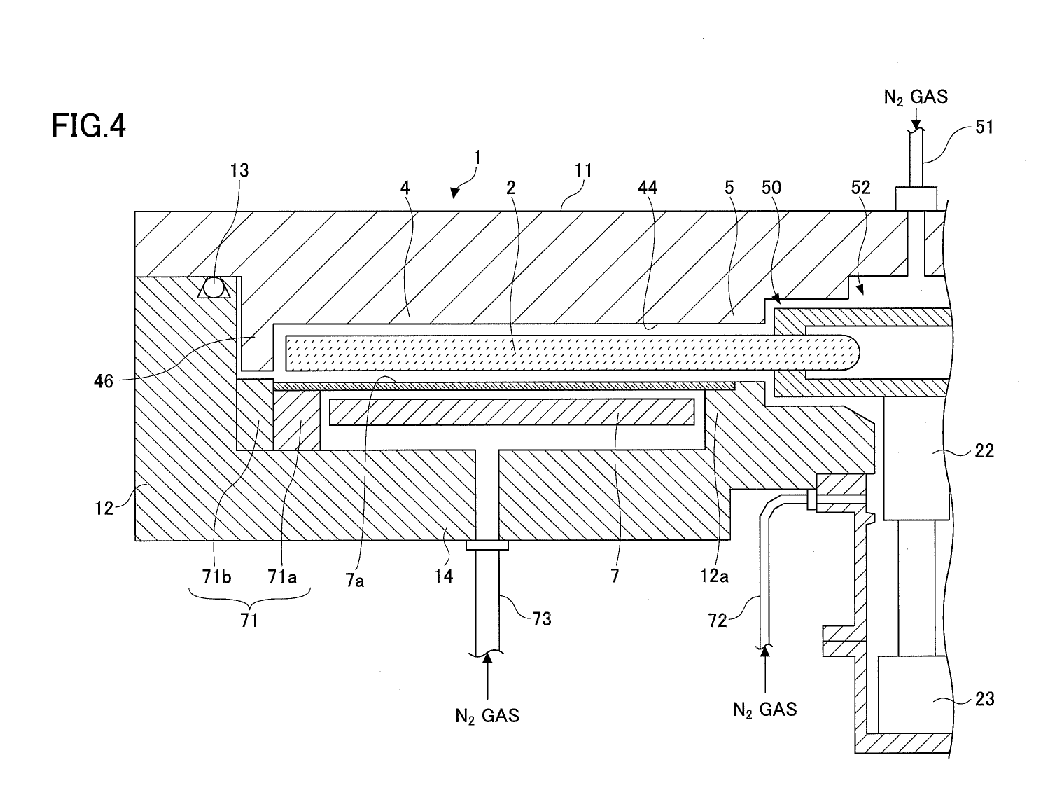

In the following, the configuration of a substrate processing apparatus according to a first embodiment of the present invention is described. FIG. 1 is a schematic cross-sectional view of the substrate processing apparatus according to the first embodiment of the present invention. FIG. 2 is a schematic plan view of the substrate processing apparatus according to the first embodiment of the present invention. FIG. 3 is a partial cross-sectional view illustrating separation areas of the substrate processing apparatus according to the first embodiment of the present invention. FIG. 4 is another partial cross-sectional view of the substrate processing apparatus according to the first embodiment of the present invention.

As illustrated in FIGS. 1 and 2, the substrate processing apparatus according to the embodiment of the present invention includes a vacuum chamber 1 having a substantially circular planar shape, and a turntable 2 that is arranged within the vacuum chamber 1 such that the center of the vacuum chamber 1 corresponds to the rotational center of the turntable 2.

The vacuum chamber 1 is a process chamber to process a wafer W while accommodating the wafer W. The vacuum chamber 1 includes a chamber body 12 having a cylindrical shape with a bottom, and a ceiling plate 11 that is detachably arranged on an upper surface of the chamber body 12 and is sealed airtight to the upper surface via a sealing member 13 such as an O-ring.

The turntable 2 has a center portion that is fixed to a cylindrical core portion 21. The core portion 21 is fixed to an upper end of a rotary shaft 22 extending in the vertical direction. The rotary shaft 22 penetrates through a bottom portion 14 of the vacuum chamber 1 and has a lower end that is attached to a drive unit 23 for rotating the rotary shaft 22 around a vertical axis. The rotary shaft 22 and the drive unit 23 are accommodated in a cylindrical case 20 having an opening formed at its upper face. The case 20 has a flange portion formed at its upper face that is attached airtight to a bottom surface of the bottom portion 14 of the vacuum chamber 1, and in this way, an internal atmosphere within the case 20 may be maintained airtight from an external atmosphere of the case 20.

As illustrated in FIG. 2, a plurality (e.g., five in the illustrated example) of circular concave portions 24 that are capable of accommodating a plurality of semiconductor wafers corresponding to substrates (hereinafter referred to as “wafer W”) are arranged along a rotational direction (circumferential direction) on the surface of the turntable 2. Note that in FIG. 2, for convenience, the wafer W is illustrated in only one of the concave portions 24. The concave portion 24 has an inner diameter that is slightly larger (e.g., larger by 4 mm) than the diameter of the wafer W (e.g., 300 mm), and a depth that is approximately equal to the thickness of the wafer W. Thus, when the wafer W is placed in the concave portion 24, the surface of the wafer W and the surface of the turntable 2 (i.e., surface of the region where the wafer W is not placed) may be substantially flush. Also, a number (e.g., 3) of through holes (not shown) are formed at a bottom face of the concave portion 24 such that lift pins (not shown) for supporting the back face of the wafer W and lifting the wafer W may be arranged to penetrate through the through holes.

Also, as illustrated in FIG. 2, reaction gas nozzles 31 and 32, separation gas nozzles 41 and 42, and an etching gas supply unit 90 are arranged above the turntable 2. In the illustrated example, the etching gas supply unit 90, the separation gas nozzle 41, the reaction gas nozzle 31, the separation gas nozzle 42, and the reaction gas nozzle 32 are spaced apart along the circumferential direction of the vacuum chamber 1 in the recited order as viewed clockwise (rotational direction of the turntable 2) from a transfer opening 15 (described below). Note that the reaction gas nozzle 31 is an example of a first reaction gas supply unit, and the reaction gas nozzle 32 is an example of a second reaction gas supply unit.

In the present embodiment, an example of the substrate processing apparatus including not only an etching area but also a film deposition area is described, but the substrate processing apparatus may be configured as an etching apparatus including only the etching gas supply unit 90 provided in the etching area or only the etching gas supply unit 90 and the separation gas nozzle 41 and 42 without the reaction gas nozzles 31 and 32 to be provided in the film deposition area. However, in the following embodiments, examples of the substrate processing apparatus including both of the etching area and the film deposition area are described hereinafter.

The reaction gas nozzles 31 and 32 respectively include gas introduction ports 31a and 32a corresponding to base portions that are fixed to an outer peripheral wall of the chamber body 12. The reaction gas nozzles 31 and 32 are introduced into the vacuum chamber 1 from the outer peripheral wall of the vacuum chamber 1. Also, the reaction gas nozzles 31 and 32 are arranged to extend parallel with respect to the turntable 2 along the radial directions of the chamber body 12.

The separation gas nozzles 41 and 42 respectively include gas introduction ports 41a and 42a corresponding to base portions that are fixed to the outer peripheral wall of the chamber body 12. The separation gas nozzles 41 and 42 are introduced into the vacuum chamber 1 from the outer peripheral wall of the vacuum chamber 1. The separation gas nozzles 41 and 42 are arranged to extend parallel with respect to the turntable 2 along the radial directions of the chamber body 12.

Note that the etching gas supply unit 90 is described below.

The reaction gas nozzle 31 may be made of quartz, for example, and is connected to a supply source of a Si (silicon)-containing gas that is used as a first reaction gas via a pipe and a flow regulator (not shown), for example. The reaction gas nozzle 32 may be made of quartz, for example, and is connected to a supply source of an oxidizing gas that is used as a second reaction gas via a pipe and a flow regulator (not shown), for example. The separation gas nozzles 41 and 42 are each connected to supply sources of separation gases via a pipe and a flow rate regulating valve (not shown), for example.

Note that organic amino silane gas may be used as the Si-containing gas, and O₃ (ozone) gas or O₂ (oxygen) gas may be used as the oxidizing gas, for example. Also, N₂ (nitrogen) gas and Ar (argon) gas may be used as the separation gases, for example.

The reaction gas nozzles 31 and 32 have a plurality of gas discharge holes 33 that open toward the turntable 2 (see FIG. 3). The gas discharge holes 33 may be arranged at intervals of 10 mm, for example, along the length direction of the reaction gas nozzles 31 and 32, for example. An area below the reaction gas nozzle 31 corresponds to a first process area P1 for causing adsorption of the Si-containing gas to the wafer W. An area below the reaction gas nozzle 32 corresponds to a second process area P2 for oxidizing the Si-containing gas that has been adsorbed to the wafer W at the first process area P1. Also, an area below the etching gas supply unit 90 corresponds to a third process area P3 to supply an etching gas for etching a reaction product deposited on the wafer W.

Here, because the first process area P1 is an area provided to supply a source gas to the wafer W, the first process area P1 may be referred to as a source gas supply area P1. Because the second process area P2 is an area provided to supply a reaction gas that can produce a reaction product by reacting with the source gas to the wafer W, the second process area P2 may be referred to as a reaction gas supply area P2. Also, because the third process area P3 is an area provided to perform an etching process on the wafer W, the third process area P3 may be referred to as an etching area P3.

Referring to FIGS. 2 and 3, convex portions 4 protruding toward the turntable 2 from bottom face regions of the ceiling plate 11 near the separation gas nozzles 41 and 42 are provided in the vacuum chamber 1. The convex portions 4 and the separation gas nozzles 41 and 42 form separation areas D. The convex portion 4 is fan-shaped in planar view and has a top portion that is cut into a circular arc shape. In the present embodiment, the inner arc of the convex portion 4 is connected to a protruding portion 5 (described below) and the outer arc of the convex portion 4 is arranged along an inner peripheral surface of the chamber body 12 of the vacuum chamber 1.

FIG. 3 is a partial cross-sectional view of the vacuum chamber 1 along a concentric circle to the outer circumference of the turntable 2 from the reaction gas nozzle 31 to the reaction gas nozzle 32. As illustrated in FIG. 3, the vacuum chamber 1 includes a first ceiling surface 44 corresponding to the bottom face of the convex portion 4 that is low and flat, and a second ceiling surface 45 that is higher than the first ceiling surface 44 and is arranged at both sides of the first ceiling surface 44 in the circumferential direction.

As illustrated in FIG. 2, the convex portion 4 is fan-shaped in planar view and has a top portion that is cut into an arc shape. Also, as illustrated in FIG. 3, a groove portion 43 extending in a radial direction is formed at the center of the convex portion 4 in the circumferential direction, and the separation gas nozzle 42 is accommodated within this groove portion 43. Note that another groove portion 43 is similarly formed in the other convex portion 4, and the separation gas nozzle 41 is accommodated within this groove portion 43. Also, the reaction gas nozzles 31 and 32 are arranged in spaces below the higher second ceiling surface 45. The reaction gas nozzles 31 and 32 are spaced apart from the second ceiling surface 45 to be arranged close to the wafer W. As illustrated in FIG. 3, note that for convenience of explanation, the space below the higher second ceiling surface 45 where the reaction gas nozzle 31 is arranged is referred to as “space 481”, the space below the higher second ceiling surface 45 where the reaction gas nozzle 32 is arranged is referred to as “space 482.”

The first ceiling surface 44 forms a separation space H corresponding to a narrow space between the first ceiling surface 44 and the surface of the turntable 2. The separation space H can separate the Si-containing gas supplied from the first area P1 and the oxidizing gas supplied from the second area P2 from each other. Specifically, when N₂ gas is discharged from the separation gas nozzle 42, N₂ gas discharged from the separation gas nozzle 42 flows toward the space 481 and the space 482 through the separation space H. At this time, because N₂ gas flows through the narrow separation space H that has a smaller volume compared to the spaces 481 and 482, the pressure in the separation space H can be made higher than the pressure in the spaces 481 and 482. That is, a pressure barrier may be created between the spaces 481 and 482. Also, the N₂ gas flowing from the separation space H into the spaces 481 and 482 act as counter-flows against the flow of the Si-containing gas from the first area P1 and the flow of the oxidizing gas from the second area P2. Thus, the Si-containing gas and the oxidizing gas may be substantially prevented from flowing into the separation space H. In this way, the Si-containing gas and the oxidizing gas are prevented from mixing and reacting with each other in the vacuum chamber 1.

Referring to FIG. 2, the protruding portion 5 is arranged around the outer periphery of the core portion 21 that fixes the turntable 2, and the protruding portion 5 is arranged on the bottom surface of the ceiling plate 11. In the present embodiment, the protruding portion 5 is connected to a rotational center side portion of the convex portion 4, and a bottom surface of the protruding portion 5 is arranged to be flush with the first ceiling surface 44.

Note that for convenience of explanation, FIG. 2 illustrates a cross-section of the chamber body 12 cut along a position that is higher than the second ceiling surface 45 and lower than the separation gas nozzles 41 and 42.

FIG. 1, referred to above, is a cross-sectional view of the substrate processing apparatus along line I-I′ of FIG. 2 illustrating a region where the second ceiling surface 45 is arranged. On the other hand, FIG. 4 is a partial cross-sectional view of the substrate processing apparatus illustrating a region where the first ceiling surface 44 is arranged.

As illustrated in FIG. 4, a bent portion 46 that is bent into an L-shape to face an outer edge face of the turntable 2 is formed at a peripheral portion (portion toward the outer edge of the vacuum chamber 1) of the fan-shaped convex portion 4. The bent portion 46, like the convex portion 4, prevents the two reaction gases from entering the separation space H from both sides of the separation area D and prevents the two reaction gases from mixing with each other. The fan-shaped convex portion 4 is arranged at the ceiling plate 11, and the ceiling plate 11 is arranged to be detachable from the chamber body 12. Thus, a slight gap is formed between an outer peripheral face of the bent portion 46 and the chamber body 12. Note that dimensions of a gap between an inner peripheral face of the bent portion 46 and an outer edge face of the turntable 2, and the gap between the outer peripheral face of the bent portion 46 and the chamber body 12 may be substantially the same as the height dimension of the first ceiling surface 44 with respect to the surface of the turntable 2, for example.

In the separation area D, an inner peripheral wall of the chamber body 12 is arranged into a substantially vertical plane that is in close proximity with the outer peripheral face of the bent portion 46 as illustrated in FIG. 4. Note, however, that in regions other than the separation area D, the inner peripheral wall of the chamber body 12 may have a portion recessed toward a region facing the outer edge face of the turntable 12 to the bottom portion 14 as illustrated in FIG. 1, for example. In the following, for convenience of explanation, such a recessed portion having a rectangular cross section is referred to as “exhaust region E”. More specifically, the exhaust region E that communicates with the first process area P1 is referred to as “first exhaust region E1”, and the exhaust region E that communicates with the second process area P2 is referred to as “second exhaust region E2” as illustrated in FIG. 2. Further, a first exhaust port 61 and a second exhaust port 62 are respectively formed at the bottom of the first exhaust region E1 and the second exhaust region E2. As illustrated in FIG. 1, the first exhaust port 61 and the second exhaust port 62 are each connected to an evacuation unit such as a vacuum pump 64 via an exhaust pipe 63. Also, a pressure regulating unit 65 is arranged at the exhaust pipe 63.

As illustrated in FIGS. 1 and 4, a heater unit 7 as a heating unit may be arranged in a space between the turntable 2 and the bottom portion 14 of the vacuum chamber 1, and a wafer W arranged on the turntable 2 may be heated to a predetermined temperature according to a process recipe via the turntable 2. Also, a ring-shaped cover member 71 for preventing gas from entering an area under the turntable 2 is arranged at a lower side of a peripheral edge portion of the turntable 2. The cover member 71 acts as a partition member for separating the atmosphere of a region extending from the space above the turntable 2 to the exhaust regions E1 and E2 and the atmosphere of a space where the heater unit 7 is arranged.

The cover member 71 includes an inner member 71a that is arranged to face an outer edge portion of the turntable 2 and a portion extending further outward from this outer edge portion from the lower side, and an outer member 71b that is arranged between the inner member 71a and an inner wall face of the vacuum chamber 1. In the separation area D, the outer member 71b is arranged near the bent portion 46, at the lower side of the bent portion 46, which is formed at the outer edge portion of the convex portion 4. The inner member 71a is arranged to surround the entire periphery of the heater unit 7 at the lower side of the outer edge portion of the turntable 2 (and the portion extending slightly outward from the outer edge portion).

A protrusion 12a is formed at a part of the bottom portion 14 toward the rotational center of the space where the heater unit 7 is disposed. The protrusion 12a protrudes upward to approach the core portion 21 at a center portion of the bottom surface of the turntable 2. A narrow space is formed between the protrusion 12a and the core portion 21. Also, a narrow space is provided between an outer peripheral face of the rotary shaft 22 that penetrates through the bottom portion 14 and the inner peripheral face of a through hole for the rotary shaft 22. Such narrow spaces are arranged to be in communication with the case 20. Further, a purge gas supply pipe 72 for supplying N₂ gas as a purge gas is arranged at the case 20.

Also, a plurality of purge gas supply pipes 73 for purging the space accommodating the heater unit 7 are arranged at the bottom portion 14 of the vacuum chamber 1 at intervals of a predetermined angle along the circumferential direction below the heater unit 7 (only one of the purge gas supply pipes 73 is illustrated in FIG. 4). Also, a lid member 7a is arranged between the heater unit 7 and the turntable 2 in order to prevent gas from entering the region where the heater unit 7 is located. The lid member 7a is arranged to extend in the circumferential direction to cover a region between an inner wall of the outer member 71b (upper face of the inner member 71a) and an upper edge portion of the protrusion 12a. The lid member 7a may be made of quartz, for example.

Also, a separation gas supply pipe 51 is connected to a center portion of the ceiling plate 11 of the vacuum chamber 1. The separation gas supply pipe 51 is configured to supply N₂ gas as a separation gas to a space 52 between the ceiling plate 11 and the core portion 21. The separation gas supplied to the space 52 is discharged toward the periphery of the turntable 2 along a wafer mounting area side surface of the turntable 2 via a narrow space 50 between the protruding portion 5 and the turntable 2. The pressure within the space 50 can be maintained at a higher pressure than the pressure within the space 481 and the space 482 by the separation gas. That is, by providing the space 50, the Si-containing gas supplied to the first process area P1 and the oxidizing gas supplied to the second process area P2 may be prevented from passing through a center region C (see FIG. 1) to mix with each other. In other words, the space 50 (or the center region C) may have a function similar to that of the separation space H (or separation area D).

Further, as illustrated in FIG. 2, the transfer opening 15 for transferring the wafer W corresponding to a substrate between an external transfer arm 10 and the turntable 2 is arranged at a side wall of the vacuum chamber 1. The transfer opening 15 may be opened/closed by a gate valve (not shown). Note that the wafer W may be transferred back and forth between the concave portion 24 corresponding to the wafer mounting region of the turntable 2 and the transfer arm 10 when the concave portion 24 is positioned to face the transfer opening 15. Accordingly, lift pins that penetrate through the concave portion 24 to lift the wafer W from its back face and a lift mechanism for the lift pins (not shown) are arranged at a portion below the turntable 2 corresponding to a transfer position for transferring the wafer W.

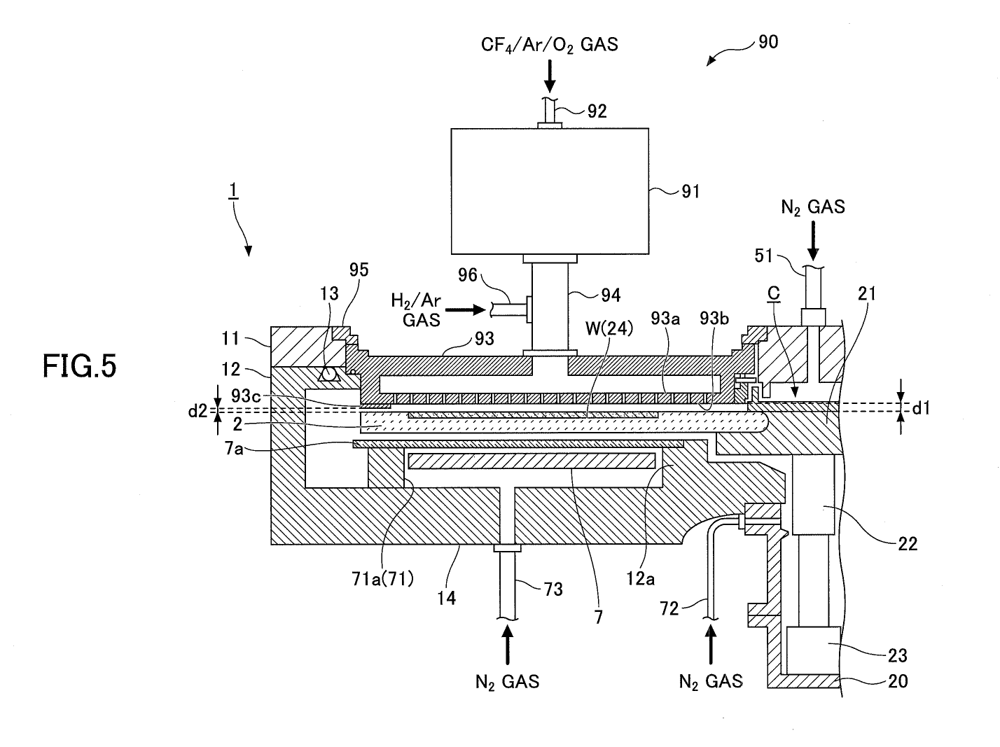

In the following, the etching gas supply unit 90 is described with reference to FIGS. 2, 5 and 6. FIG. 5 is a partial cross-sectional view illustrating a third process area P3 of the substrate processing apparatus according to the present embodiment.

The etching gas supply unit 90 is provided so as to face the turntable 2 in the third process area (etching area) P3. The etching gas supply unit 90 supplies an activated fluorine-containing gas to a film deposited on the wafer W, thereby etching the film. As illustrated in FIGS. 2 and 5, the etching gas supply unit 90 includes a plasma generation unit 91, an etching gas supply pipe 92, a shower head unit 93, a pipe 94, and a hydrogen-containing gas supply unit 96. Note that the shower head unit 93 is an example of an etching gas discharging unit. Hence, for example, an etching gas nozzle may be used instead of the shower head unit 93.

The plasma generation unit 91 activates a fluorine-containing gas supplied from the etching gas supply pipe 92 using a plasma source. The plasma source is not particularly limited as long as it is capable of activating the fluorine-containing gas to generate F (fluorine) radicals. For example, an inductively coupled plasma (ICP), a capacitively coupled plasma (CCP), or a surface wave plasma (SWP) may be used as the plasma source.

The etching gas supply pipe 92 has one end that is connected to the plasma generation unit 91 to supply the fluorine-containing gas to the plasma generation unit 91. The other end of the etching gas supply pipe 92 may be connected to an etching gas supply source that stores the fluorine-containing gas via an on-off valve and a flow regulator, for example. Note that a variety of fluorine-containing gases are available for the fluorine-containing gas as long as the fluorine-containing gas can etch the film deposited on the wafer W. Specifically, for example, fluorine-containing gases including hydrofluorocarbons such as CHF₃ (trifluoromethane), fluorocarbons such as CF₄ (carbon tetrafluoride) for etching a silicon oxide film may be used. Further, gases such as Ar gas and/or O₂ gas may be added to these fluorine-containing gases at appropriate amounts, for example.

The shower head unit 93 is connected to the plasma generation unit 91 via the pipe 94. The shower head unit 93 supplies the fluorine-containing gas that has been activated by the plasma generation unit 91 into the vacuum chamber 1. The shower head unit 93 is fan-shaped in planar view and is pressed downward along the circumferential direction by a press member 95 that is formed along the outer edge of the fan shape. The press member 95 is fixed to the ceiling plate 11 by a bolt or the like (not shown), and in this way, the internal atmosphere of the vacuum chamber 1 may be maintained airtight. The distance between a bottom face of the shower head unit 93 when it is secured to the ceiling plate 11 and a surface of the turntable 2 may be arranged to be about 0.5 mm to about 5 mm, for example. An area below the shower head unit 93 corresponds to the third process area P3 for etching a silicon oxide film, for example. In this way, F radicals contained in the activated fluorine-containing gas that is supplied into the vacuum chamber 1 via the shower head unit 93 may efficiently react with the film deposited on the wafer W.

A plurality of gas discharge holes 93a are arranged at the shower head unit 93. In view of the difference in angular velocity of the turntable 2, fewer gas discharge holes 93a are arranged at a rotational center side of the shower head unit 93, and more gas discharge holes 93a are arranged at an outer peripheral side of the shower head unit 93. The total number of the gas discharge holes 93a may be several tens to several hundreds, for example. Also, the diameter of the plurality of gas discharge holes 93a may be about 0.5 mm to 3 mm, for example. The activated fluorine-containing gas supplied to the shower head unit 93 may be supplied to the space between the turntable 2 and the shower head unit 93 via the gas discharge holes 93a.

However, even when more gas discharge holes 93a are arranged at the outer peripheral side, the etching rate is likely to significantly decrease at the outer peripheral side than at the rotational center side, and the decrease in etching rate cannot be efficiently prevented by just increasing a ratio of the gas discharge holes 93a at the outer peripheral side to the gas discharge holes 93a at the rotational center side in many cases. In general, in a film deposition process, by increasing the density of gas discharge holes in a predetermined area and a supply rate of a gas, a deposition rate in the predetermined area can be increased. However, in the etching process, even when the supply rate of the etching gas is increased, the etching rate does not necessarily increase in many cases. Although the reason will be described later by using experimental data, it is conceivable that this is because a rate-limiting factor of the etching process is not a supply amount of the etching gas but whether or not the reaction occurs. In other words, even if sufficient etching gas is supplied, when conditions of the etching reaction are not satisfied, a sufficient etching rate cannot be achieved. The conditions of the etching reaction mean a state of having sufficient etching reaction energy, and the etching reaction energy can be kept high under high pressure and high temperature.

Hence, the substrate processing apparatus according to the first embodiment is configured to include a downward protruding surface 93c that protrudes downward on the outer peripheral portion so as to prevent a decrease in pressure at the outer peripheral portion inside the etching area P3. The downward protruding surface 93c is provided outside the concave portions 24 of the turntable 2 so as to face the surface of the turntable 2 at the outer peripheral portion. The downward protruding surface 93c forms a gap d2 that is narrower than a gap d1 between an inner area of a lower surface 93b of the shower head unit 93 and the surface of the turntable 2 at the outer peripheral portion, thereby preventing the etching gas discharged from the gas discharge holes 93a from going outward. In addition, the downward protruding surface 93c prevents decrease in and the etching reaction energy at the outer peripheral portion of the etching area P3. This prevents the etching rate at the outer peripheral portion of the etching area P3 from decreasing, and allows a uniform etching rate to be obtained as a whole across the etching area P3.

Here, the outer peripheral portion of the turntable 2 may be configured to be larger than the usual turntable 2 so as to sufficiently ensure the area of the narrow gap d2 formed between the downward protruding surface 93c and the surface of the turntable 2 in the radial direction. In other words, the diameter of the turntable 2 may be configured to be larger by expanding the area outside the concave portions 24 of the turntable 2 outward. This is because the effect of preventing the outflow of the etching gas and increasing the pressure on the peripheral side cannot be sufficiently obtained even when the clearance or gap forming the narrow gap d2 is provided if the length of the narrow gap d2 is too short in the radial direction. In FIG. 5, an example of slightly expanding the outer peripheral portion of the turntable 2 is illustrated.

Moreover, the gap d1 between the inner lower surface 93b of the shower head unit 93 and the turntable 2, and the narrow gap d2 between the downward protruding surface 83c and the surface of the turntable 2 can be set at a variety of values depending on intended use as long as the values satisfy 0<d2<d1. For example, the gap d1 may be set greater than or equal to 1 mm and less than or equal to 6 mm, and the narrow gap d2 may be set greater than zero and less than 3 mm. Specifically, the gap d1 may be set at 4 mm, and the narrow gap d2 may be set at 2 mm. Here, the gap d1 and the narrow gap d2 may be referred to as clearances d1 and d2, or distances d1 and d2.

Furthermore, the downward protruding surface 93c may be formed by attaching a plate-shaped member to the flat lower surface of the shower head unit 93, or the shower head unit 93 may be formed as a single integral component by processing the shower head unit 93 into a shape with the downward protruding surface 93c from the beginning.

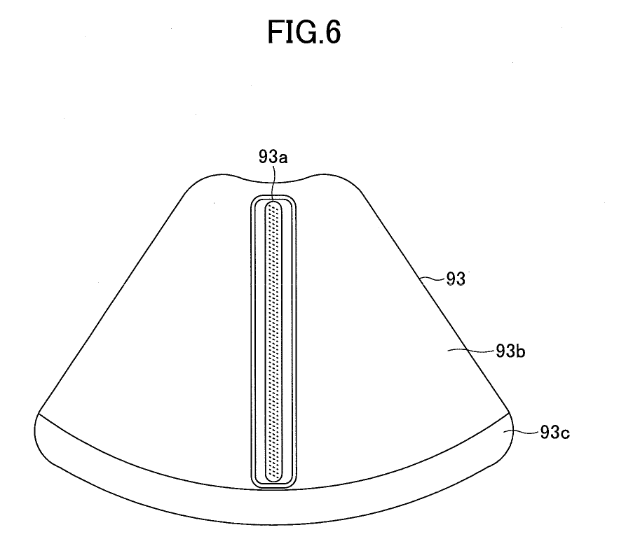

FIG. 6 is a plan view illustrating an example of a lower surface of the shower head unit 93. As illustrated in FIG. 6, the downward protruding surface 93c may be provided in a belt-like form along the outer circumference of the lower surface 93c of the fan-shaped shower head unit 93. This can uniformly prevent the pressure on the outer peripheral side of the etching area P3 from decreasing in the circumferential direction. Moreover, the gas discharge holes 93a may be provided at the center of the lower surface 93b of the shower head unit 93 in the circumferential direction so as to extend in the radial direction. This allows the etching gas to be supplied in a dispersed manner from the central side throughout the outer peripheral side of the turntable 2.

A description is given below with reference to FIG. 5 again. The pipe 94 is arranged upstream of the shower head unit 93 and connects the plasma generation unit 91 with the shower head unit 93. The hydrogen-containing gas supply unit 96 is arranged at an outer peripheral side of the pipe 94 with respect to the radial direction of the turntable 2.

The hydrogen-containing gas supply unit 96 has one end that is connected to the pipe 94 and is configured to supply a hydrogen-containing gas into the pipe 94. The other end of the hydrogen-containing gas supply unit 96 may be connected to a hydrogen-containing gas supply source via a switching valve and a flow regulator, for example.

The hydrogen-containing gas supply unit 96 is preferably arranged closer to the shower head unit 93 than the plasma generation unit 91. In this way, the hydrogen-containing gas supplied into the pipe 94 may be prevented from flowing backward into the plasma generation unit 91. In turn, H₂ plasma may be prevented from being generated in the plasma generation unit 91. As a result, contamination by a metal constituting the plasma generation unit 91 may be prevented, and the life of the devices and components constituting the plasma generation unit 91 may be prolonged, for example. Also, a flow rate difference may be easily created between the flow rate of the hydrogen-containing gas supplied to the rotational center side of the turntable 2 and the flow rate of the hydrogen-containing gas supplied to the outer peripheral side of the turntable 2, for example.

Note that a gas mixture of H₂ (hydrogen) gas and Ar gas (hereinafter referred to as “H₂/Ar gas”) may be used as the hydrogen-containing gas, for example. Also, the supply flow rate of H₂ gas may be controlled to be greater than or equal to 1 sccm and less than or equal to 50 sccm, for example, and the supply flow rate of the Ar gas may be controlled to be greater than or equal to 500 sccm and less than or equal to 10 slm, for example.

Note that in the example of FIG. 5, one hydrogen-containing gas supply unit 96 is arranged at an outer peripheral side of the pipe 94 with respect to a radial direction of the turntable 2. However, the present invention is not limited to such an arrangement. For example, the hydrogen-containing gas supply unit 96 may be arranged ahead of the pipe 94 or behind the pipe 94 with respect to the rotational direction of the turntable 2. Also, in some examples, a plurality of the hydrogen-containing gas supply units 96 may be arranged at the pipe 94.

Further, as illustrated in FIG. 1, the substrate processing apparatus includes a control unit 100 configured by a computer for performing control operations of the substrate processing apparatus. The control unit 100 includes a memory storing a program for causing the substrate processing apparatus to implement a substrate processing method according to an embodiment of the present invention under control of the control unit 100 as described below. The program includes a set of steps for implementing operations of the substrate processing apparatus as described below and may be installed in the control unit 100 from a storage unit 100 that may be configured by a hard disk, a compact disk, a magnetic optical disk, a memory card, a flexible disk, or some other type of computer-readable storage medium.

(Substrate Processing Method)

In the following, an exemplary substrate processing method using the substrate processing apparatus according to the above-described embodiment is described. Note that an example of a method of forming a SiO₂ film in a via hole corresponding to a concave pattern that is formed in the wafer W is described below. Also, note that in the example described below, it is assumed that a Si-containing gas is used as the first reaction gas, an oxidizing gas is used as the second reaction gas, and a gas mixture of CF₄, Ar gas, and O₂ gas (hereinafter referred to as “CF₄/Ar/O₂ gas”) is used as the fluorine-containing gas.

First, a gate valve (not shown) is opened, and a wafer W is transferred from the exterior by the transfer arm 10 via the transfer opening 15 to be placed within one of the concave portions 24 of the turntable 2 as illustrated in FIG. 2. The transfer of the wafer W may be accomplished by lifting the lift pins (not shown) from the bottom side of the vacuum chamber 1 via the through holes that are formed at the bottom face of the concave portion 24 when the concave portion 24 comes to a halt at a position facing the transfer opening 15. Such a transfer of the wafer W may be performed with respect to each of the five concave portions 24 of the turntable 2 by intermittently rotating the turntable 2 to place a wafer W in each of the concave portions 24, for example.

Then, the gate valve is closed, and air is drawn out of the interior of the vacuum chamber 1 by the vacuum pump 64. Then, N₂ gas as a separation gas is discharged at a predetermined flow rate from the separation gas nozzles 41 and 42, and N₂ gas is discharged at a predetermined flow rate from the separation gas supply pipe 51 and the purge gas supply pipes 72 and 73. In turn, the pressure regulating unit 65 adjusts the pressure within the vacuum chamber 1 to a preset processing pressure. Then, the heater unit 7 heats the wafers W up to 450° C., for example, while the turntable 2 is rotated clockwise at a rotational speed of 60 rpm, for example.

Then, a film deposition process is performed. In the film forming process, a Si-containing gas is supplied from the reaction gas nozzle 31, and an oxidizing gas is supplied from the reaction gas nozzle 32. Note that in this process, no gas is supplied from the etching gas supply unit 90.

When one of the wafers W passes the first process area P1, the Si-containing gas, as a source gas that is supplied from the reaction gas nozzle 31, is adsorbed to the surface of the wafer W. Then, as the turntable 2 is rotated, the wafer W having the Si-containing gas adsorbed to its surface passes the separation area D including the separation gas nozzle 42 where the wafer W is purged. Thereafter, the wafer W enters the second process area P2. In the second process area P2, the oxidizing gas is supplied from the reaction gas nozzle 32, and Si components contained in the Si-containing gas is oxidized by the oxidizing gas. As a result, SiO₂ corresponding to a reaction product of the oxidization is deposited on the surface of the wafer W.

The wafer W that has passed the second process area P2 passes the separation area D including the separation gas nozzle 41 where the wafer W is purged. Then, the wafer W again enters the first process area P1. Then, the Si-containing gas that is supplied from the reaction gas nozzle 31 is adsorbed to the surface of the wafer W.

As described above, in the film deposition process, the turntable 2 is consecutively rotated a plurality of times while supplying the first reaction gas and the second reaction gas into the vacuum chamber 1 but without supplying a fluorine-containing gas into the vacuum chamber 1. In this way, SiO₂ corresponding to the reaction product may be deposited on the surface of the wafer W and a SiO₂ film (silicon oxide film) may be formed on the wafer W surface.

Also, if necessary or desired, after the SiO₂ film has been formed to a predetermined thickness, the supply of the Si-containing gas from the reaction gas nozzle 31 may be stopped but the oxidizing gas may be continuously supplied from the reaction gas nozzle 32 while rotation of the turntable 2 is continued. In this way, a modification process may be performed on the SiO₂ film.

By executing the film deposition process as described above, the SiO₂ film may be deposited in a via hole corresponding to one example of a concave pattern. The SiO₂ film that is first deposited in the via hole may have a cross-sectional shape substantially corresponding to the concave shape of the via hole.

Then, an etching process is performed. In the etching process, the SiO₂ film is etched to have a V-shaped cross-sectional shape. In the following, specific process steps of the etching process are described.

As illustrated in FIG. 2, the supply of the Si-containing gas and the oxidizing gas from the reaction gas nozzles 31 and 32 are stopped, and N₂ gas as a purge gas is supplied. The temperature of the turntable 2 is set to a temperature of about 600° C., for example, that is suitable for etching. The rotation speed of the turntable 2 may be set to 60 rpm, for example. In such a state, the CF₄/Ar/O₂ gas is supplied from the shower head unit 93 of the etching gas supply unit 90, the H₂/Ar gas is supplied from the hydrogen-containing gas supply unit 96 at a preset flow rate, for example, and the etching process is started.

Note that at this time, the turntable 2 is rotated at a relatively low speed such that the SiO₂ film may be etched to have a V-shaped cross-sectional shape. By etching the SiO₂ film in the via hole into a V-shape, a hole having a wide opening at its top portion may be formed in the SiO₂ film, and in this way, when filling the hole with a SiO₂ film in a subsequent film deposition process, the SiO₂ may reach the bottom of the hole such that bottom-up characteristics may be improved and void generation may be prevented in the film forming process.

Here, as described above, because the downward protruding surface 93a is provided at the outer peripheral portion of the lower surface 93b of the shower head unit 93, the decrease in etching energy on the outer peripheral side inside the etching area P3 can be prevented, and the etching rate can be made more uniform.

Thus, the fluoride-containing gas and the hydrogen-containing gas are supplied into the vacuum chamber 1 without supplying the first reaction gas and the second reaction gas while continuously rotating the turntable 2 a plurality of times. Thus, the SiO₂ film is etched.

Next, the above-described film deposition process is performed again. In the film deposition process, a SiO₂ film is further deposited on the SiO₂ film etched into the V-shape in the etching process, and the film thickness is increased. Because the film is deposited on the SiO₂ film etched into the V-shape, an entrance (upper portion) is not filled with the film in the film deposition, and the film can be deposited on and from the bottom portion of the SiO₂ film.

Next, the above-described etching process is performed again. In the etching process, the SiO₂ film is etched in a V-shape.

The above-described film deposition process and the etching process are alternately repeated at necessary number of times, and the via hole is filled with the SiO₂ film while preventing a void from being generated in the SiO₂ film. The number of repetitions of these processes may be set at an appropriate number of times depending on a shape including an aspect ratio of a concave-shaped pattern of the via hole and the like. For example, when the aspect ratio is high, the number of repetitions increases. Moreover, the number of repetitions for filling the via hole is expected to be more than the number of repetitions for filling the trench.

Here, in the present embodiment, an example of filling the concave-shaped pattern formed in the surface of the wafer W with the film by repeating the film deposition process and the etching process, has been described, the present invention is not limited to this example.

For example, after carrying a wafer W on which a film is preliminarily deposited into the vacuum chamber 1, only the etching process needs to be performed on the wafer W.

Furthermore, for example, the first reaction gas, the second reaction gas, the fluoride-containing gas and the hydrogen-containing gas are supplied into the vacuum chamber 1 at the same time while continuously rotating the turntable 2 a plurality of times, the film deposition process and the etching process may be performed once for each rotation of the turntable 2. In addition, a cycle of performing each of the film deposition process and the etching process once may be repeated a plurality of times.

According to the substrate processing apparatus and the substrate processing method according to the first embodiment, an uniform etching process can be performed on a film deposited on a wafer W by providing the downward protruding surface 93c for forming the narrow gas d2 between the surface of the turntable 2 and the lower surface of the downward protruding surface 93c at the outer peripheral portion of the lower surface 93b of the shower head unit 93.

### Second Embodiment

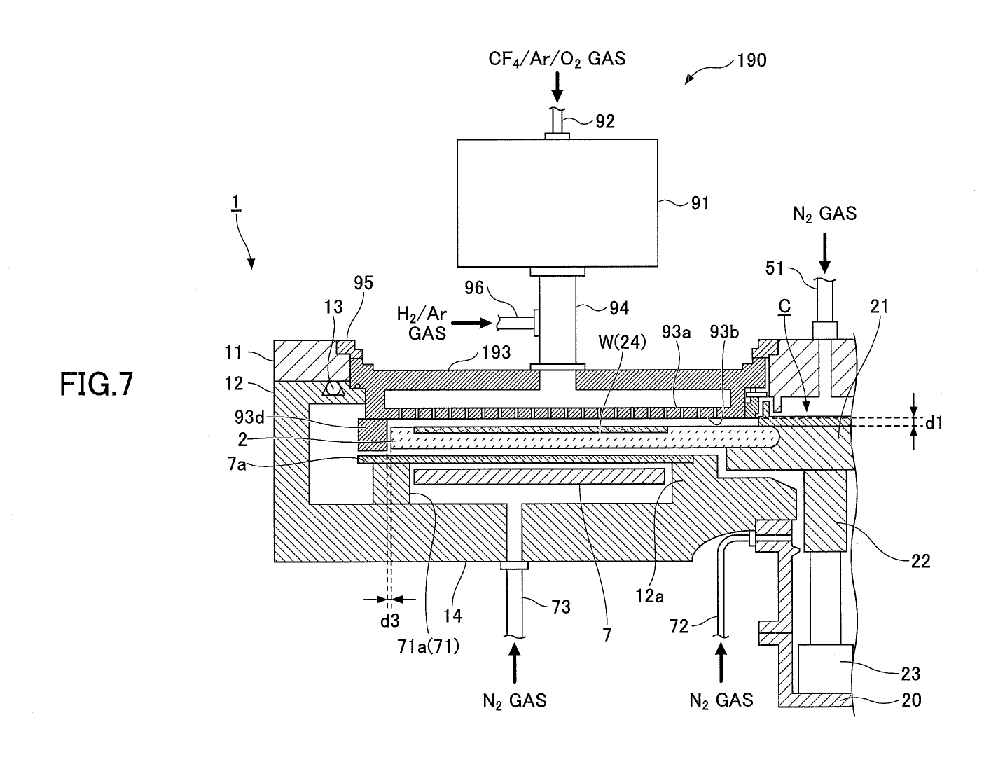

FIG. 7 is a diagram illustrating an example of a substrate processing apparatus according to a second embodiment of the present invention. The substrate processing apparatus according to the second embodiment differs from the substrate processing apparatus according to the first embodiment in that a shower head unit 193 in the etching area P3 has a different configuration from the shower head unit 93 of the first embodiment. However, because the other components of the substrate processing apparatus according to the second embodiment are the same as those of the substrate processing apparatus according to the first embodiment, only different points are described below. Also, the same numerals are used for components corresponding to the components of the substrate processing apparatus according to the first embodiment, and the description is omitted or simplified.

As illustrated in FIG. 7, the shower head unit 193 of the substrate processing apparatus according to the second embodiment includes a downward protruding portion 93d that protrudes downwards so as to cover an outer side surface of the turntable 2 and forms a narrow gap d3 between an inner side surface of the downward protruding portion 93d and the outer side surface of the turntable 2. Thus, the narrow gap d3 may be formed between the outer side surface of the turntable 2 and the inner side surface of the downward protruding portion 93d, not between the upper surface of the turntable 2 and the lower surface of the downward protruding portion 93d. Even in this case, the narrow gap d3 can prevent an etching gas inside the etching area P3 from flowing outward, and can prevent a decrease in pressure on the outer peripheral side inside the etching area P3.

In FIG. 7, the distance of a gap d1 between a lower surface 93b in a central area of the shower head unit 193 and the upper surface of the turntable 2 is made the same as the distance of the gap d1 of the substrate processing apparatus according to the first embodiment. The gap d1 and the narrow gap d3 may be set at a variety of values as long as the gap d1 and the narrow gas d3 satisfy 0<d3<d1 similar to the first embodiment. For example, the gap d1 may be longer than or equal to 1 mm and shorter than or equal to 6 mm, and the narrow gap d3 may be longer than zero and shorter than 3 mm. More specifically, the gap d1 may be set at 4 mm, and the narrow gap d3 may be set at 2 mm.

However, because the narrow gap d3 has a shorter facing range (smaller area) to the turntable 2 than the narrow gap d2 of the first embodiment and because the etching gas is likely to be slightly easier to flow out than the first embodiment, the narrow gap d3 is, for example, preferably set at 2 mm or smaller.

In the first embodiment, the turntable 2 needs to have a dimension capable of facing the downward protruding surface 93c at the outer peripheral portion in the radial direction (diameter or radius), but in the second embodiment, because the downward protruding portion 93d is arranged to face the outer side surface of the turntable 2, the turntable 2 does not have to ensure an extra area outside the concave portions 24, and the turntable 2 can be formed smaller than the turntable 2 of the first embodiment.

FIG. 8 is a diagram illustrating the positional relationship between the downward protruding portion 93d and the turntable 2 in a state of removing the shower head unit 193. As illustrated in FIG. 8, the downward protruding portion 93d is formed into an arc shape provided outside the outer side surface of the turntable 2 along the outer circumference of the turntable 2.

Because the substrate processing method according to the second embodiment is the same as the substrate processing method according to the first embodiment, the description is omitted.

According to the substrate processing apparatus of the second embodiment, the pressure on the outer peripheral side in the etching area P3 can be prevented from decreasing, and a uniform etching can be achieved while forming the turntable 2 so as to have a small diameter.

### Third Embodiment

In a substrate processing apparatus according to a third embodiment, an example of preventing a decrease in etching reaction energy by preventing a decrease in temperature on the outer peripheral side in an etching area, is described below. The prevention of the decrease in etching reaction energy can be achieved by not only preventing a pressure in the etching area from decreasing but also preventing the temperature from decreasing.

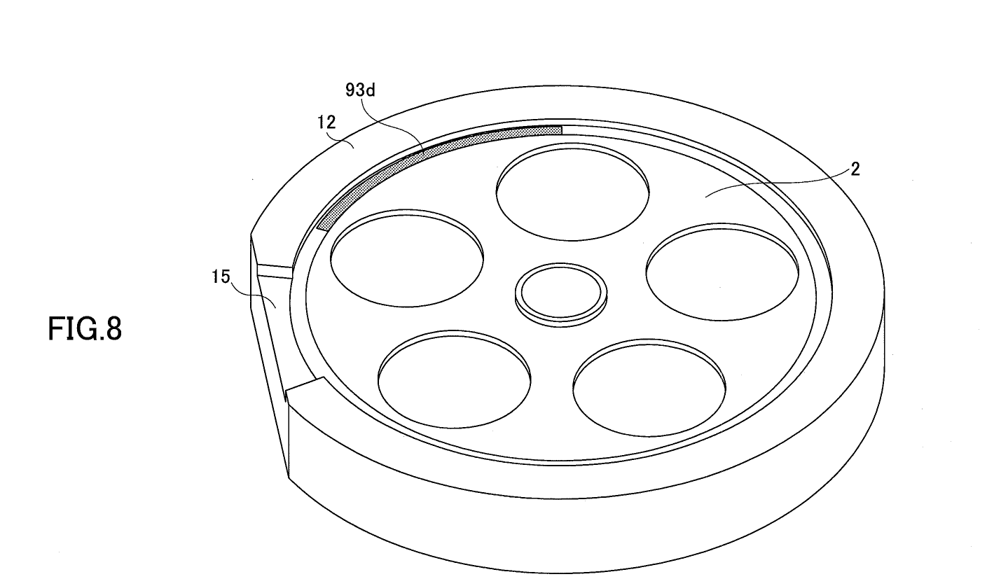

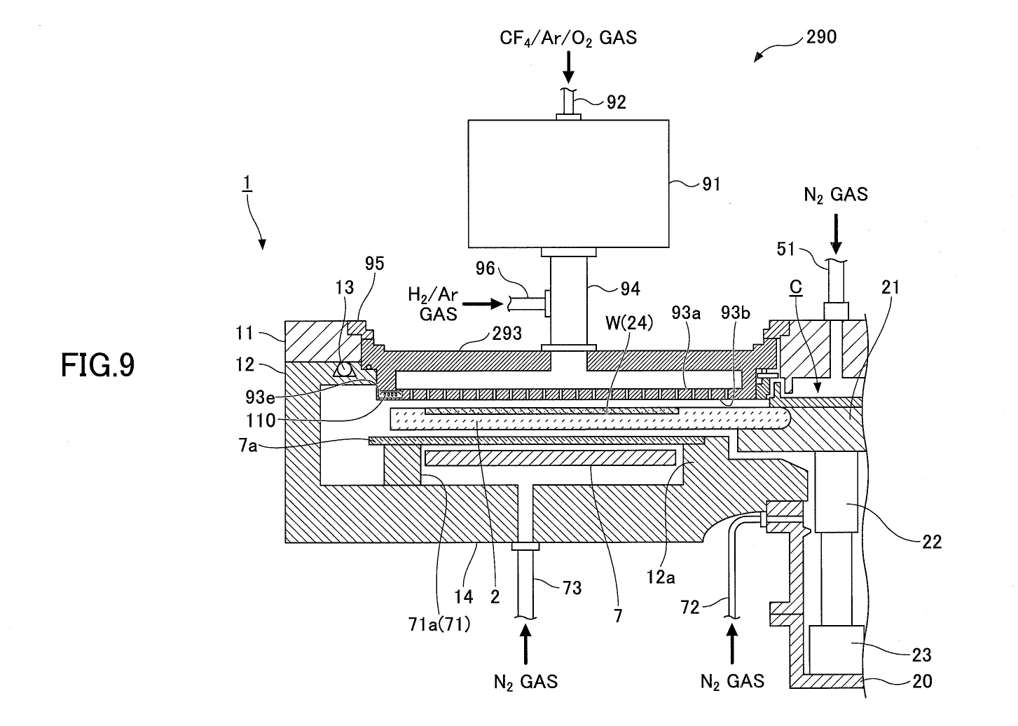

FIG. 9 is a diagram illustrating an example of a substrate processing apparatus according to a third embodiment of the present invention. In the substrate processing apparatus according to the third embodiment, because only a configuration of a shower head unit 293 in the etching area P3 differs from the shower head units 93 and 193 of the substrate processing apparatuses according to the first and second embodiments, only the different points are described below. Same numerals as those of the first and second embodiments are used for the other components, and the description is omitted.

In FIG. 9, a housing space 93e is formed in an outer peripheral portion of the shower head unit 293, and a heater 110 is housed in the housing space 93e. Thus, by providing the heater 110 at the outer peripheral portion of the shower head unit 293 to heat the outer peripheral portion in the etching area P3, the decrease in etching reaction energy at the outer peripheral side of the etching area P3 can be prevented.

In FIG. 9, although the housing space 93e is formed in the outermost potion of the shower head unit 293 and the heater 110 is provided therein, for example, the heater 110 may be provided closer to the center. The heater 110 can be arranged at a variety of locations of the shower head unit 293 depending on the intended use as long as the heater 110 can locally heat the outer peripheral portion of the etching area P3.

Moreover, a variety of heating units can be used as the heater 110 depending on the intended use. For example, a carbon heater may be used as the heater 110.

In a substrate processing method according to the third embodiment, the heater 110 just has to start heating the outer peripheral portion together with the heater unit 7 at the same time when the heater unit 7 starts heating the turntable 2, as described in the substrate processing method according to the first embodiment. Otherwise, the heater 110 does not necessarily start in accordance with the heating start time of the heater unit 7, and the heater 110 may start at a variety of timings before stating the etching process as long as the temperature of the heater 110 is stabilized when starting the etching process.

Because the other processes are the same as the substrate processing method according to the first embodiment, the description is omitted.

According to the substrate processing apparatus and the substrate processing method according to the third embodiment, by providing the heater 110 in the shower head unit 293, a decrease in etching reaction energy in the etching area P3 can be prevented, and a uniform etching can be achieved.

### Fourth Embodiment

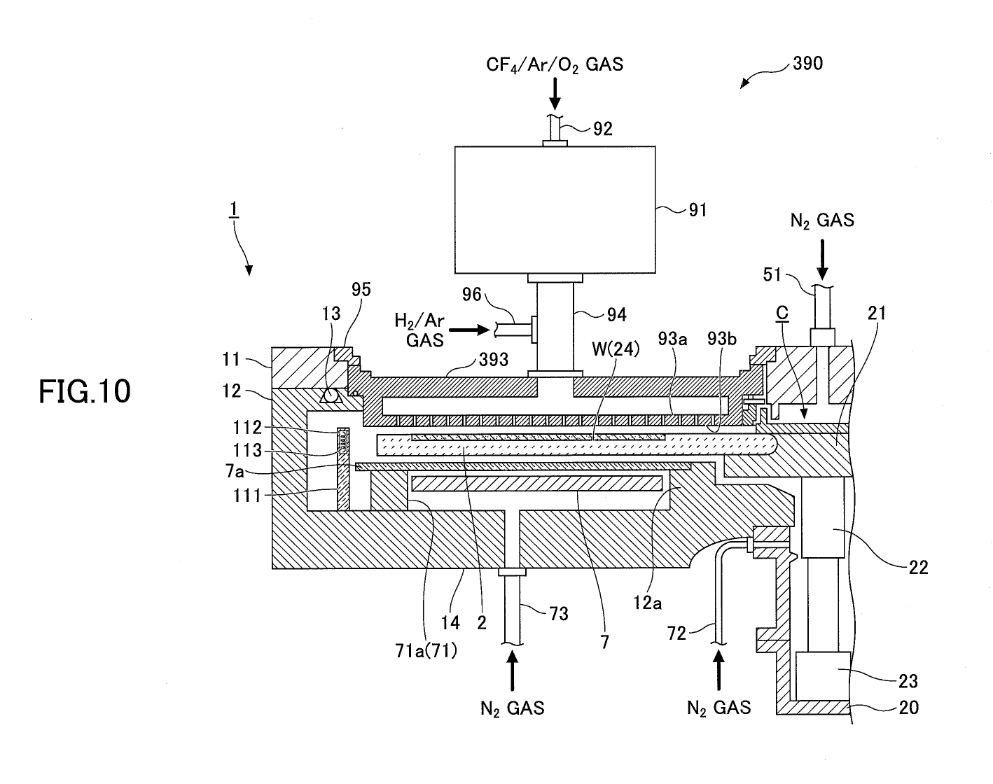

FIG. 10 is a diagram illustrating an example of a substrate processing apparatus according to a fourth embodiment of the present invention. The substrate processing apparatus according to the fourth embodiment includes a side wall part 111 at a location outside the turntable 2 in the etching area P3, and a heater 113 in a housing space 112 formed inside the side wall part 111.

In this manner, the substrate processing apparatus according to the fourth embodiment is configured to include the heater 113 arranged outside the turntable 2 in the etching area P3 so as to prevent etching reaction energy at an outer peripheral portion of the etching area P3 from decreasing by heating the etching area P3 from the outside of the turntable. This makes it possible to prevent a temperature in an outer area of the etching area P3 from decreasing and to prevent an etching rate at the outer peripheral portion from decreasing.

The side wall part 111 is preferably provided as close as possible to the turntable 2, but can be disposed at any location between the inner side wall of the chamber body 12 and the turntable 2 (more particularly, the lid member 7a) depending on the intended use. Moreover, the heater 113 can be provided on the inner side wall of the chamber body 12 without providing the side wall part 111.

The side wall part 111 can be made of a variety of materials, but for example, can be made of quartz.

A variety of heating units can be used as the heater 113, and for example, a carbon heater can be used as the heater 113, as well as the substrate processing apparatus according to the third embodiment.

Because a substrate processing method according to the fourth embodiment is the same as the substrate processing method according to the third embodiment, the description is omitted.

According to the substrate processing apparatus and the substrate processing method according to the fourth embodiment, by simply disposing the heater 113 on the periphery side of the etching area P3 without complicating a structure of a shower head unit 393 and by heating the etching area P3 from the outside, the decrease in etching reaction energy on the outer peripheral side can be prevented.

### WORKING EXAMPLES AND COMPARATIVE EXAMPLES

Next, working examples of performing the substrate processing apparatuses and the substrate processing methods according to the embodiments of the present invention are described with comparative examples. Same numerals are used for components corresponding to the components as described above for convenience of explanation.

### Comparative Example 1

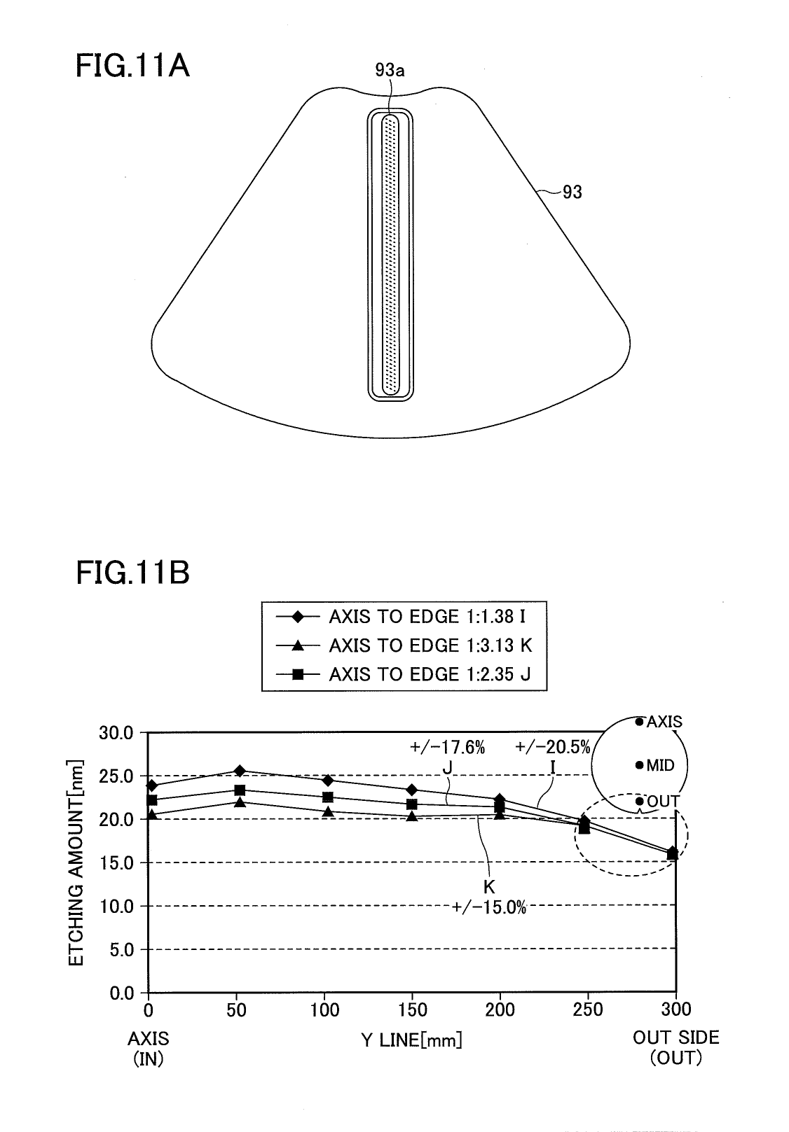

FIGS. 11A and 11B are diagrams showing an experiment and a result thereof of measuring an amount of etching while changing the hole distribution of gas discharge holes 93a of a shower head unit 93.

FIG. 11A is a diagram for explaining an experiment of a comparative example 1. In the comparative example 1, whether providing more gas discharge holes 93a at a peripheral portion of the shower head unit 93 than at the central portion (on the rotational axis side) results in the improvement of uniformity of an etching, is examined.

The experiment was performed with respect to three cases of setting ratios of the gas discharge holes 93a from the axial side to the outer periphery at 1:1.38 (characteristics I), 1:2.35 (characteristics J), and 1:3.13 (characteristics K). Experimental conditions are set at a temperature of 550 degrees C., and a pressure of 1 Torr inside the vacuum chamber 1, and a rotational speed of the turntable 2 at 60 rpm. With respect to an etching gas, CF₄ is supplied at a flow rate of 10 sccm; O₂ is supplied at a flow rate of 60 sccm; and Ar is supplied at a flow rate of 7 slm.

FIG. 11B is a diagram showing the distribution in the resulting amounts of etching in three of the cases of the characteristics I, J and K. In FIG. 11B, the horizontal axis indicates a coordinate on the peripheral side starting from the axis side toward the peripheral side (mm), and the vertical axis indicates an amount of etching. As shown in FIG. 11B, the characteristics I through K show approximately the same characteristics in a range from 250 to 300 mm on the outer side of a wafer W with a diameter of 300 mm. In other words, the characteristics I through K shown in FIG. 11 mean that increasing a supply of an etching gas does not lead to an increase in etching amount. Furthermore, as shown in FIG. 11B, the amount of etching on the peripheral side is smaller than the amount of etching on the central side. Hence, the amount of etching at the outer peripheral portion needs to be increased to achieve uniform etching, but it is noted that it is difficult to solve the decrease in etching amount at the outer peripheral portion by just increasing the number of the gas discharge holes 93a at the outer peripheral portion.

It is conceivable that this is because the rate-limiting factor of the etching process is not the supply amount of the etching gas but the generation of the reaction. To solve this, the energy necessary for an etching reaction needs to be increased at the outer peripheral portion.

### Comparative Example 2

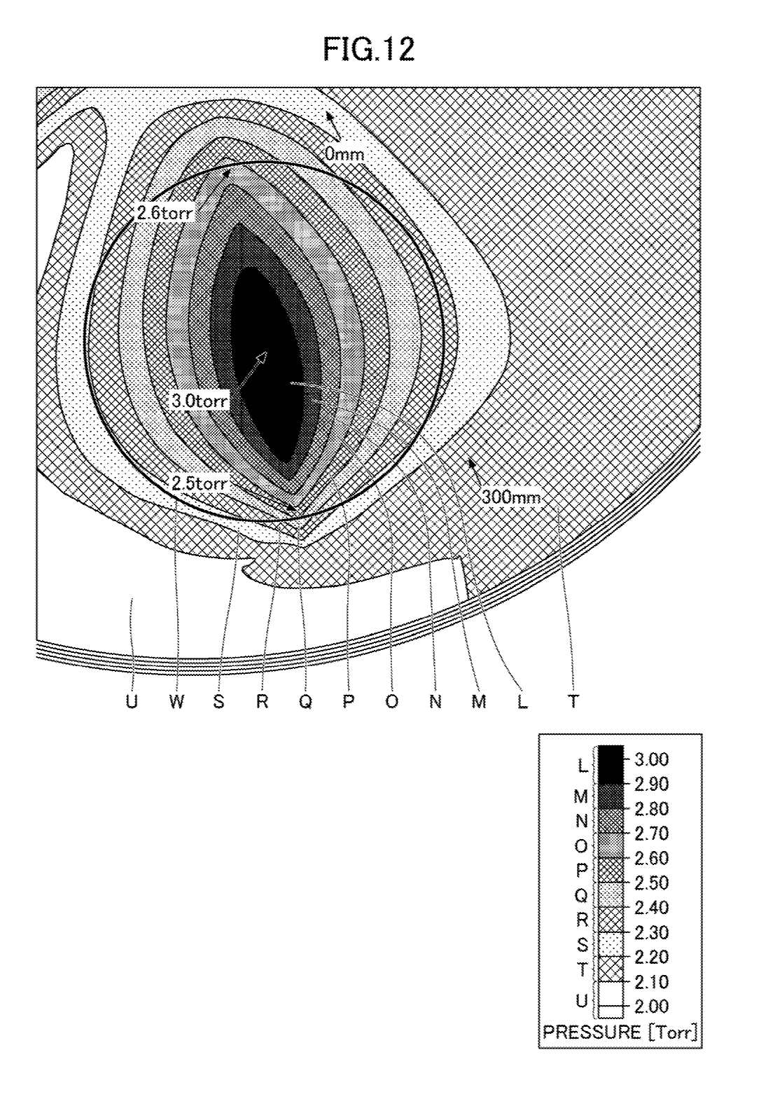

FIG. 12 is a diagram showing a simulation result of a pressure distribution below a shower head unit 93 of a substrate processing apparatus according to a comparative example 2. The substrate processing apparatus according to the comparative example 2 does not include any measures to prevent a decrease in etching reaction energy at the outer peripheral portion of the etching area P3.

When a pressure distribution below the shower head unit 93 is measured by using such a substrate processing apparatus, the result shown in FIG. 12 is obtained. In FIG. 12, same levels of pressure areas are expressed by L, M, N, O, P, Q, R, S, T, and U in descending order of pressure. According to the result of FIG. 12, the pressure is the highest at the center of the wafer W, which is 3 Torr, and the pressures are decreased at both ends on the axis side and the periphery side, which are 2.6 Torr and 2.5 Torr, respectively. Although the pressures at both ends do not differ greatly, as shown in FIG. 11B, the actual amount of etching at the outer peripheral portion is smaller than the actual amount of etching at the central portion. Hence, measures to increase the pressure at the outer peripheral portion are needed.

### Working Example 1

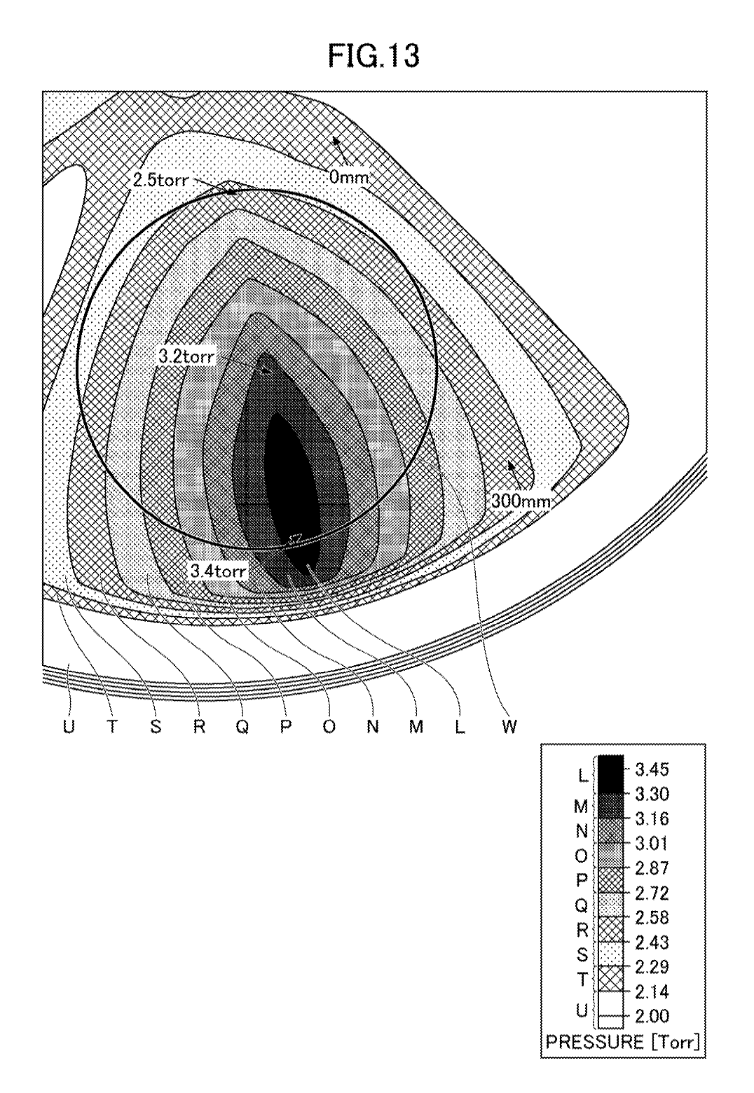

FIG. 13 is a diagram illustrating a simulation result of a pressure distribution below a shower head unit 93 of a substrate processing apparatus according to a working example 1. The substrate processing apparatus according to the working example 1 has a configuration similar to the substrate processing apparatus according to the first embodiment, and a gap d1 between a lower surface 93b of the shower head unit 93 and the turntable 2 is set at 4 mm, and a narrow space d2 between a downward protruding surface 93c provided on the outer peripheral side of the shower head unit 93 and the turntable 2 is set at 2 mm.

As shown in FIG. 13, when using the substrate processing apparatus according to the working example 1, a pressure at the outer peripheral portion of a wafer W is the highest, which is a pressure of 3.5 Torr, and a pressure on the axis side is low, which is a pressure of 2.5 Torr. Thus, according to the substrate processing apparatus of the working example 1, the pressure at the outer peripheral portion in the etching area P3 can be selectively increased so as to increase the pressure at the outer peripheral portion of the wafer W.

(Calculation of Preferable Etching Rates)

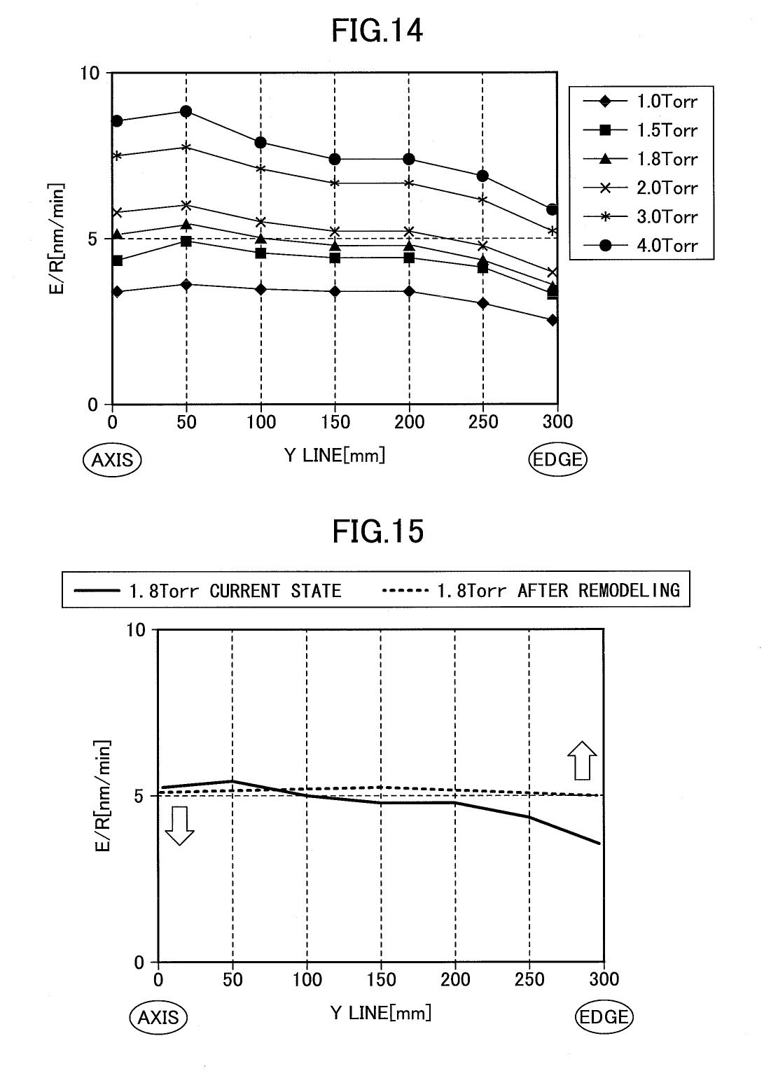

FIG. 14 is a diagram showing a pressure dependency of an etching rate of the substrate processing apparatus according to the comparative example 2. As shown in FIG. 14, when a pressure is 1 Torr, the etching rate is the lowest, and the etching rate can be increased as a whole as the pressure is increased to 1.5 Torr, 1.8 Torr, 2.0 Torr, 3.0 Torr, and 4.0 Torr.

FIG. 15 is a simulation result of calculating a preferable etching rate based on characteristics of the pressure dependency of the etching rate of FIG. 14. In FIG. 15, when the pressure inside the vacuum chamber 1 is set at 1.8 Torr, the etching rate of the substrate processing apparatus according to the comparative example 2 is expressed by characteristics B. In this case, dispersion of the etching rate on the Y axis is ±19.7%.

In contrast, in FIG. 15, when the pressure inside the vacuum chamber is set at 1.8 Torr, the etching rate of the etching process by the substrate processing apparatus according to the working example 1 is expressed by characteristics A. In this case, dispersion of the etching rate on the Y axis is ±2.57%, and it is noted that uniformity of the etching rate is greatly improved.

Thus, the substrate processing apparatus according to the working example 1 can more widely improve the uniformity of the etching process than the substrate processing apparatus according to the comparative example 2.

As discussed above, according to the substrate processing apparatus and the substrate processing method of the embodiments, by having a structure of preventing the etching reaction energy on the periphery side in the etching area P3 from decreasing, the uniformity of the etching process can be greatly improved.

In this manner, according to the embodiments of the present invention, the uniform etching process can be achieved.

All examples and conditional language recited herein are intended for pedagogical purposes to aid the reader in understanding the embodiments and the concepts contributed by the inventor to furthering the art, and are to be construed as being without limitation to such specifically recited examples and conditions, nor does the organization of such examples in the specification relate to a showing of superiority or inferiority of the embodiments. Although the method of manufacturing the silicon oxide film has been described in detail, it should be understood that the various changes, substitutions, and alterations could be made hereto without departing from the spirit and scope of the invention.

What is claimed is:

1. A substrate processing apparatus comprising:
a vacuum chamber;
a turntable provided in the vacuum chamber and including a substrate receiving area formed in a surface along a circumferential direction thereof;
an etching area provided at a predetermined area along the circumferential direction of the turntable;
an etching gas supply unit provided in the etching area that faces the surface of the turntable and includes gas discharge holes arranged to extend in a radial direction of the turntable; and
a reaction energy decrease prevention unit configured to prevent a decrease in etching reaction energy in an outer area of the turntable in the etching area.

2. The substrate processing apparatus according to claim 1, wherein the reaction energy decrease prevention unit is a pressure decrease prevention unit configured to prevent a decrease in pressure in the outer area of the turntable in the etching area.

3. The substrate processing apparatus according to claim 2, wherein the pressure decrease prevention unit is a narrow gap formation unit to form a first gap outside the substrate receiving area in the etching area so that the first gap is narrower than a second gap formed between a lower surface of the etching gas supply unit and the surface of the turntable.

4. The substrate processing apparatus according to claim 3, wherein the first gap is formed between a part of the lower surface of the etching gas supply unit and the surface of the turntable.

5. The substrate processing apparatus according to claim 4, wherein the narrow gap formation unit is a downward protruding surface provided on the lower surface of the etching gas supply unit along a circumference of the etching gas supply unit with a predetermined width.

6. The substrate processing apparatus according to claim 3,
wherein the narrow gap formation unit is a downward protruding portion formed on a peripheral portion of the etching gas supply unit beyond the turntable so as to cover an outer side surface of the turntable from an outside, and
the first gap is formed between the outer side surface of the turntable and an inner side surface of the downward protruding portion.

7. A substrate processing apparatus according to claim 1, wherein the reaction energy prevention unit is a temperature decrease prevention unit configured to prevent a decrease in temperature in the outer area of the turntable in the etching area.

8. The substrate processing apparatus according to claim 7, wherein the temperature decrease prevention unit is a heater provided in a peripheral portion of the etching gas supply unit, or outside the turntable in the etching area.

9. The substrate processing apparatus according to claim 1, wherein the etching gas supply unit is a fan-shaped shower head.

10. The substrate processing apparatus according to claim 9, further comprising:
a plasma source for supplying a plasma etching gas to the etching gas supply unit.

11. The substrate processing apparatus according to claim 1, further comprising:
a film deposition area provided at a predetermined area apart from the etching area in the circumferential direction of the turntable.

12. The substrate processing apparatus according to claim 11,
wherein the film deposition area includes a source gas supply area configured to supply a source gas to the substrate, and
a reaction gas supply area provided apart from the source gas supply area in the circumferential direction of the turntable and configured to supply a reaction gas capable of producing a reaction product by reacting with the source gas to the substrate.

13. The substrate processing apparatus according to claim 12, further comprising:
a separation area provided between the source gas supply area and the reaction gas supply area and configured to supply a purge gas to the substrate.

14. A substrate processing method comprising:
placing a substrate on a substrate receiving area formed in a surface of a turntable along a circumferential direction of the turntable that is provided in a process chamber; and
performing an etching process on the substrate by rotating the turntable to cause the substrate to pass through an etching area provided at a predetermined area in the circumferential direction of the turntable,
wherein the etching process is performed while preventing a decrease in etching reaction energy in an outer area of the turntable in the etching area.

15. The substrate processing method according to claim 14, wherein the decrease in etching reaction energy in the outer area is prevented by performing the etching process on the substrate while forming a first gap between an etching gas supply unit configured to supply an etching gas to the substrate in the etching gas area and the turntable at a predetermined area outside the substrate receiving area so that the first gap is narrower than a second gap formed between an inner area other than the predetermined area in order to prevent a decrease in pressure in the predetermined area.

16. The substrate processing method according to claim 15, wherein the predetermined area is formed in a periphery in the surface of the turntable.

17. The substrate processing method according to claim 15, wherein the predetermined area is a side portion of the turntable.

18. The substrate processing method according to claim 14, wherein the decrease in etching reaction energy in the outer area of the turntable in the etching area is prevented by locally heating the outer area of the etching area.

19. The substrate processing method according to claim 14, further comprising:
depositing a film on the substrate by causing the substrate passing through a film deposition area provided apart from the etching area in the circumferential direction of the turntable,
wherein the etching process is performed on the film deposited on the substrate by the step of depositing the film on the substrate.

20. The substrate processing method according to claim 19,
wherein the depositing the film on the substrate includes supplying a source gas to the substrate, and
supplying a reaction gas reactable with the source gas to the substrate to deposit a reaction product on the substrate.
